(19) United States
(12) Patent Application Publication
(10) Pub. No.: US 2026/0040773 A1
(43) Pub. Date: Feb. 5, 2026

(54) DISPLAY DEVICE

(71) Applicant: Japan Display Inc., Tokyo (JP)

(72) Inventors: Takamitsu FUJIMOTO, Tokyo (JP); Sho YANAGISAWA, Tokyo (JP); Ryota TAKASAKI, Tokyo (JP); Takayuki SUZUKI, Tokyo (JP)

(73) Assignee: Japan Display Inc., Tokyo (JP)

(21) Appl. No.: 19/286,253

(22) Filed: Jul. 31, 2025

(30) Foreign Application Priority Data
Aug. 2, 2024 (JP) 2024-127826

(51) Int. Cl. H10K 59/122; H10K 59/131

(52) U.S. Cl. CPC H10K 59/122; H10K 59/131

(57) ABSTRACT

According to one embodiment, a display device includes a display element provided in a display area, an inorganic insulating layer provided across the display area and a surrounding area, a partition provided on the inorganic insulating layer, having conductivity, and surrounding the display element, and a power supply line covered with the inorganic insulating layer. An outer edge of the display area has a round portion. The power supply line is provided along the round portion in the surrounding area and is electrically connected to the partition via a plurality of contact holes penetrating the inorganic insulating layer. The plurality of contact holes are arranged in a stair step layout along the round portion.

### CROSS-REFERENCE TO RELATED APPLICATION

This application is based upon and claims the benefit of priority from Japanese Patent Application No. 2024-127826, filed Aug. 2, 2024, the entire contents of which are incorporated herein by reference.

### FIELD

Embodiments described herein relate generally to a display device.

### BACKGROUND

Recently, display devices with organic light- emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a schematic cross-sectional view of the display device DSP along the A-B line of FIG. 2.

FIG. 4 is a schematic plan view showing some elements of the display device DSP.

FIG. 5 is a view showing an example of the layout of sealing layers SE11, SE12, and SE13 and a slit ST.

FIG. 6 is a schematic cross-sectional view of the display device DSP along the C-D line of FIG. 5.

FIG. 7 is a plan view showing an example of the shape of a partition 6 in the vicinity of a round portion RD.

FIG. 8 is a plan view showing an example of the shape of the partition 6 in the vicinity of a contact hole CH1 shown in FIG. 7.

FIG. 9 is a schematic cross-sectional view of the display device DSP along the E-F line of FIG. 8.

FIG. 10 is a schematic cross-sectional view of the display device DSP along the G-H line of FIG. 8.

FIG. 11A is a schematic cross-sectional view showing a manufacturing process of the display device.

FIG. 11B is a schematic cross-sectional view showing a process following FIG. 11A.

FIG. 11C is a schematic cross-sectional view showing a process following FIG. 11B.

FIG. 11D is a schematic cross-sectional view showing a process following FIG. 11C.

FIG. 11E is a schematic cross-sectional view showing a process following FIG. 11D.

FIG. 11F is a schematic cross-sectional view showing a process following FIG. 11E.

FIG. 12 is a plan view showing another example of the shape of the partition 6 in the vicinity of the contact hole CH1.

FIG. 13 is a plan view showing an example of the shape of the partition 6 in the vicinity of the round portion RD.

FIG. 14 is a plan view showing an example of the shape of the partition 6 in the vicinity of the contact hole CH1 shown in FIG. 13.

FIG. 15 is a plan view showing another example of the shape of the partition 6 in the vicinity of the contact hole CH1 shown in FIG. 13.

### DETAILED DESCRIPTION

The present embodiment aims to provide a display device capable of improving yields.

In general, according to one embodiment, a display device includes a display element provided in a display area for displaying an image, an inorganic insulating layer provided across the display area and a surrounding area located outside the display area, a partition provided on the inorganic insulating layer, having conductivity, and surrounding the display element in the display area, and a power supply line covered with the inorganic insulating layer. An outer edge of the display area has a round portion. The power supply line is provided along the round portion in the surrounding area and is electrically connected to the partition via a plurality of contact holes penetrating the inorganic insulating layer. The plurality of contact holes are arranged in a stair step layout along the round portion.

According to another embodiment, a display device includes a display element provided in a display area for displaying an image, an inorganic insulating layer provided across the display area and a surrounding area located outside the display area, a partition provided on the inorganic insulating layer, having conductivity, and surrounding the display element in the display area, and a power supply line covered with the inorganic insulating layer. The power supply line is electrically connected to the partition via a contact hole penetrating the inorganic insulating layer in the surrounding area. The partition is formed in a grating shape having a plurality of first extending portions and a plurality of second extending portions in the surrounding area. The plurality of first extending portions each extend in a first direction and are arranged at a first pitch in a second direction intersecting the first direction. The plurality of second extending portions each extend in the second direction and are arranged at a second pitch in the first direction. The contact hole is located at an intersection of one of the plurality of first extending portions and one of the plurality of second extending portions.

According to yet another embodiment, a display device includes a display element provided in a display area for displaying an image, an inorganic insulating layer provided across the display area and a surrounding area located outside the display area, a partition provided on the inorganic insulating layer, having conductivity, and surrounding the display element in the display area, and a power supply line covered with the inorganic insulating layer. The power supply line is electrically connected to the partition via a contact hole penetrating the inorganic insulating layer in the surrounding area. The partition is formed in a grating shape having a plurality of apertures in the surrounding area. The plurality of apertures have a first aperture, a second aperture, and a third aperture arranged at a regular pitch in a direction. The contact hole is located between the second aperture and the third aperture. A width between the first aperture and the second aperture is equivalent to a width between the second aperture and the third aperture in the partition.

The present embodiment can provide a display device capable of improving yields.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may directly contact each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

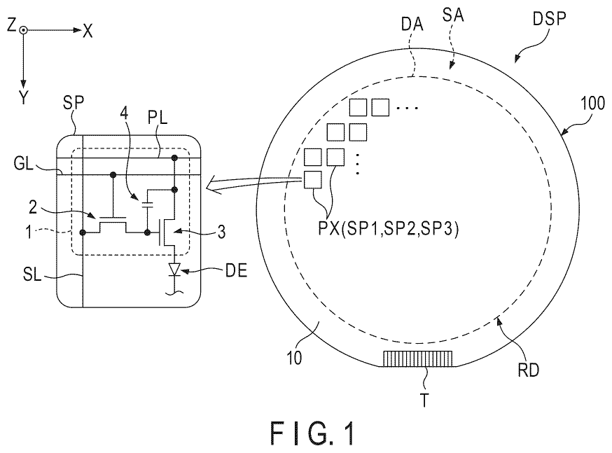

FIG. 1 is a view showing a configuration example of a display device DSP.

The display device DSP comprises a display panel 100. The display panel 100 has a display area DA for displaying an image and a surrounding area SA around the display area DA on an insulating substrate 10. The substrate 10 may be either a glass substrate or a resinous substrate having flexibility.

The outer edge of at least part of the display area DA has a round portion RD. In the illustrated example, the display area DA has a circular shape in plan view. The shape of the display area DA in plan view is not limited to the illustrated example. For example, the outer edge of the display area DA may be constituted by the round portion RD and a straight-line portion.

The display area DA comprises a plurality of pixels PX arrayed in a matrix in the first direction X and the second direction Y. Each pixel PX includes a plurality of subpixels SP that display different colors. For example, each pixel PX includes a subpixel SP1 which displays the first color, a subpixel SP2 which displays the second color, and a subpixel SP3 which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to a display element DE. In the illustrated example, the scanning lines GL extend in the first direction X and the signal lines SL extend in the second direction Y.

The configuration of the pixel circuit 1 is not limited to the example shown in the figure. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display device DSP.

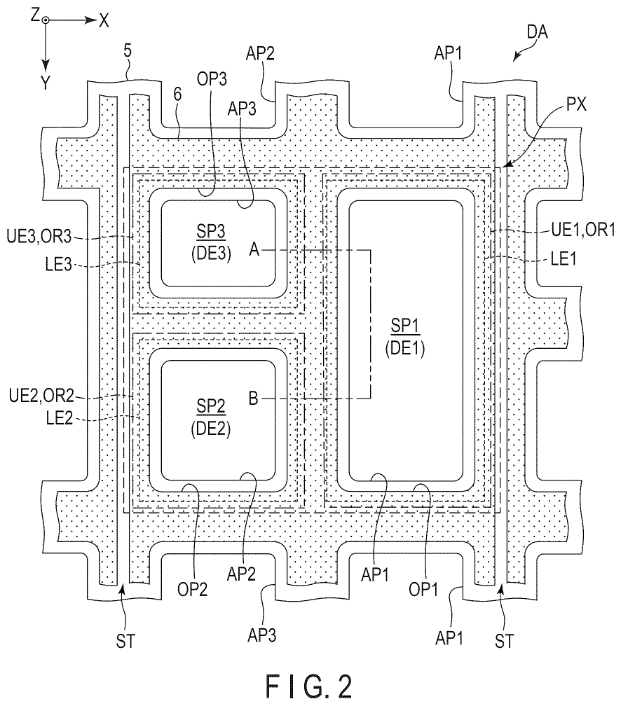

FIG. 2 is a diagram showing an example of the layout of the subpixels SP1, SP2, and SP3 which constitute one pixel PX.

In the illustrated example, the subpixels SP2 and SP3 are arranged in the second direction Y. The subpixels SP1 and SP2 are arranged in the first direction X. The subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the example of FIG. 2.

An inorganic insulating layer 5 and a partition 6 are provided in the display area DA. The inorganic insulating layer 5 has apertures AP1, AP2, and AP3 in subpixels SP1, SP2, and SP3, respectively. The inorganic insulating layer 5 having these apertures AP1, AP2, and AP3 may be called a rib.

The partition 6 overlaps the inorganic insulating layer 5 in plan view. The partition 6 is formed in a grating shape surrounding the apertures AP1, AP2, and AP3. In other words, the partition 6 has respective apertures OP1, OP2, and OP3 in the subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise display elements DE1, DE2, and DE3, respectively, as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view. For example, the organic layer OR1 has a light emitting layer that emits light in a blue wavelength range.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view. For example, the organic layer OR2 has a light emitting layer that emits light in a green wavelength range.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view. For example, the organic layer OR3 includes a light emitting layer that emits light in a red wavelength range.

In the illustrated example, the outlines of the lower electrodes LE1, LE2, and LE3 are indicated by dotted lines, and the outlines of the organic layers OR1, OR2, and OR3 and the upper electrodes UE1, UE2, and UE3 are indicated by one-dot chain line. The outlines of the respective lower electrode, organic layer, and upper electrode shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planer size of the aperture AP1, the planar size of the aperture AP2, and the planar size of the aperture AP3 differ from one another. The planer size of the aperture AP1 is greater than that of the aperture AP2. The planer size of the aperture AP2 is greater than that of the aperture AP3. The partition 6 has a plurality of slits ST.

In the illustrated example, each of the slits ST extends in the second direction Y. For example, the subpixels SP1, SP2, and SP3 constituting one pixel PX are provided between two slits ST adjacent to each other in the first direction X.

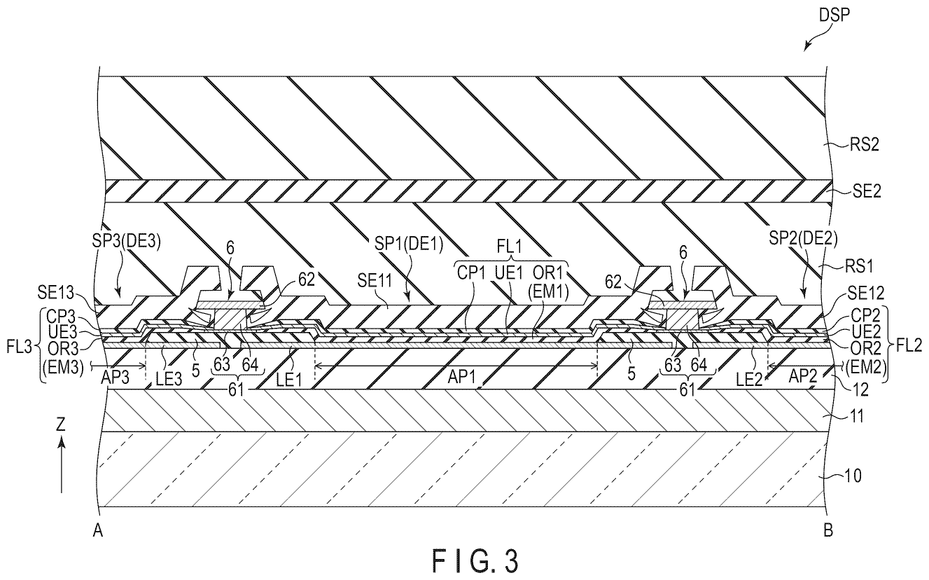

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

The insulating layer 12 is provided on the circuit layer 11. For example, the insulating layer 12 is an organic insulating layer that planarizes the uneven parts formed by the circuit layer 11.

The lower electrode LE1 of the subpixel SP1, the lower electrode LE2 of the subpixel SP2, and the lower electrode LE3 of the subpixel SP3 are provided on the insulating layer 12 and are spaced apart from one another.

The inorganic insulating layer 5 is provided on the insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2, and LE3 are connected to the pixel circuits 1 of the subpixels SP1, SP2 and SP3, respectively, through the contact holes provided in the insulating layer 12. FIG. 3 omits the illustration of the contact hole in the insulating layer 12.

The partition 6 has a conductive lower portion 61 provided on the inorganic insulating layer 5 and an upper portion 62 provided on the lower portion 61.

In the illustrated example, the lower portion 61 has a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than that of the stem layer 64. The both end portions of the bottom layer 63 protrude relative to the side surfaces of the stem layer 64.

The upper portion 62 is provided on the stem layer 64. The upper portion 62 has the width greater than that of the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the organic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the organic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the organic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 has the cap layer CP1 and a sealing layer SE11. The subpixel SP2 has the cap layer CP2 and a sealing layer SE12. The subpixel SP3 has the cap layer CP3 and a sealing layer SE13. The cap layers CP1, CP2 and CP3 function as optical adjustment layers, which improve the extraction efficiency of light emitted from the organic layers OR1, OR2, and OR3, respectively. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12, and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Cavities are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. Further, the resin layer RS1 is filled into the cavity formed on the partition 6.

The sealing layer SE2 covers the resin layer RS1. A transparent resin layer RS2 covers the sealing layer SE2.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃).

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is formed of a titanium-based material such as titanium or a titanium compound or an oxide conductive material such as indium tin oxide (ITO).

Each of the lower electrodes LE1, LE2, and LE3 is, for example, a multilayer body having a transparent layer formed of an oxide conductive material such as an indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, EM3 are formed of materials different from one another. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body having a plurality of thin films. All of the thin films are transparent and have refractive indices different from each other.

The circuit layer 11, the insulating layer 12, and the inorganic insulating layer 5, which are illustrated are provided across the display area DA and the surrounding area SA.

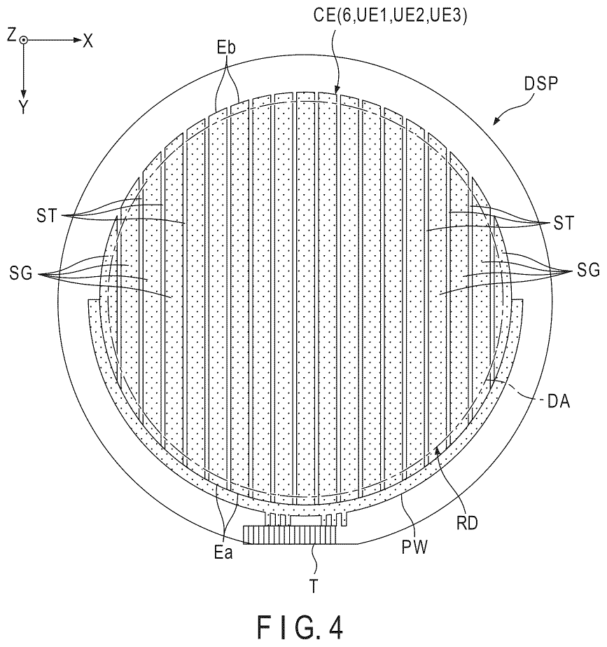

FIG. 4 is a schematic plan view showing some elements of the display device DSP.

The partition 6 and the upper electrodes UE1, UE2, and UE3 constitute a common electrode CE, which applies common voltage to the display elements DE1, DE2, and DE3. For example, the common electrode CE has a circular shape and entirely overlaps the display area DA having a circular shape.

The common electrode CE has the plurality of slits ST. Each of the slits ST intersects the display area DA. Both end portions of the slit ST reach the outer edge of the common electrode CE. By this configuration, the common electrode CE is constituted by a plurality of segments SG spaced apart from one another via each of the slits ST.

In the illustrated example, each of the slits ST and the segments SG extends in the second direction Y. Alternatively, each of the slits ST and the segments SG may extend in the first direction X. The number of the slits ST provided in the common electrode CE is not particularly limited.

Each of the plurality of segments SG has a first end portion Ea and a second end portion Eb in the extension direction of the slits ST (the second direction Y in the illustrated example). The first end portion Ea is located between the display area DA and the terminal portion T in the second direction Y. The second end portion Eb is located on the side opposite to the first end portion Ea.

In the surrounding area SA, the power supply line PW is provided along the round portion RD and is located between the display area DA and the terminal portion T in the second direction Y. Further, the power supply line PW is electrically connected to the terminal portion T.

In the first end portion Ea side, each of the segments SG is electrically connected to the power supply line PW. In the second end portion Eb side, each of the segments SG is not electrically connected to conductive members such as the power supply line PW. Common voltage is applied to each of the segments SG from the terminal portion T via the power supply line PW.

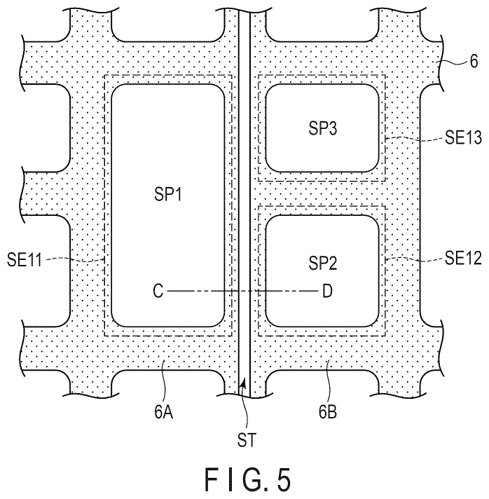

FIG. 5 is a view showing an example of the layout of the sealing layers SE11, SE12, and SE13 and the slit ST.

As indicated by broken lines, the sealing layers SE11, SE12, and SE13 are formed in island-like shapes in the respective subpixels SP1, SP2, and SP3. The sealing layer SE11 may be continuously formed across the plurality of subpixels SP1 arranged in the second direction Y.

The end portions of each of the sealing layers SE11, SE12, and SE13 entirely overlap the partition 6. In the illustrated example, none of the sealing layers SE11, SE12, and SE13 overlap the slits ST. At least part of the sealing layers SE11, SE12, and SE13 may overlap the slits ST.

The slit ST is located between the sealing layers SE11 and SE12 and between the sealing layers SE11 and SE13, and extends in the second direction Y. The slit ST divides the partition 6 in the illustrated area into two partitions 6A and 6B adjacent in the first direction X.

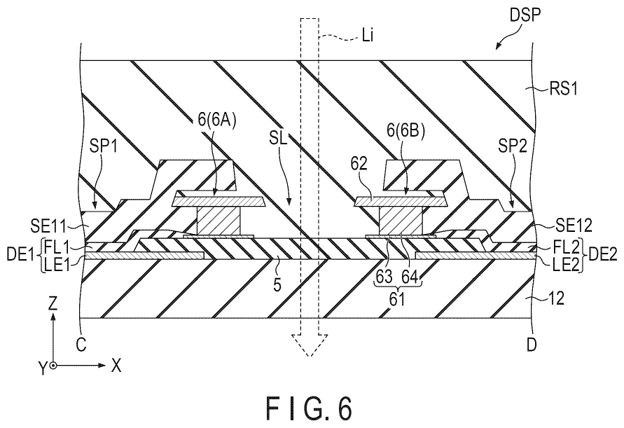

FIG. 6 is a schematic cross-sectional view of the display device DSP along the C-D line of FIG. 5. FIG. 6 omits the illustration of the elements located under the organic insulating layer 12 and the elements located above the resin layer RS1.

The slit ST corresponds to a portion of the partition 6 that penetrates the bottom layer 63 and the stem layer 64 of the lower portion 61 and the upper portion 62.

In the partitions 6A and 6B, the both end portions of the upper portion 62 protrude relative to the side surfaces of the lower portion 61 (or the side surfaces of the stem layer 64). Further, the both end portions of the bottom layer 63 protrude relative to the side surfaces of the stem layer 64.

The end portion of the sealing layer SE11 is located above the partition 6A. The sealing layer SE11 continuously covers the display element DE1 of the subpixels SP1 and part of the partition 6A.

The end portion of the sealing layer SE12 is located above the partition 6B. The sealing layer SE12 continuously covers the display element DE2 of the subpixels SP2 and part of the partition 6B.

The inorganic insulating layer 5 covers the insulating layer 12 in the slit ST, but does not have a through hole overlapping the slit ST. The resin layer RS1 is filled into the slit ST, covers the bottom layer 63, the stem layer 64, and the upper portion 62, and contacts the inorganic insulating layer 5.

None of the lower electrodes LE1, LE2, and LE3 overlap the slit ST. Thus, a transmissive area transmitting light Li can be formed between adjacent lower electrodes.

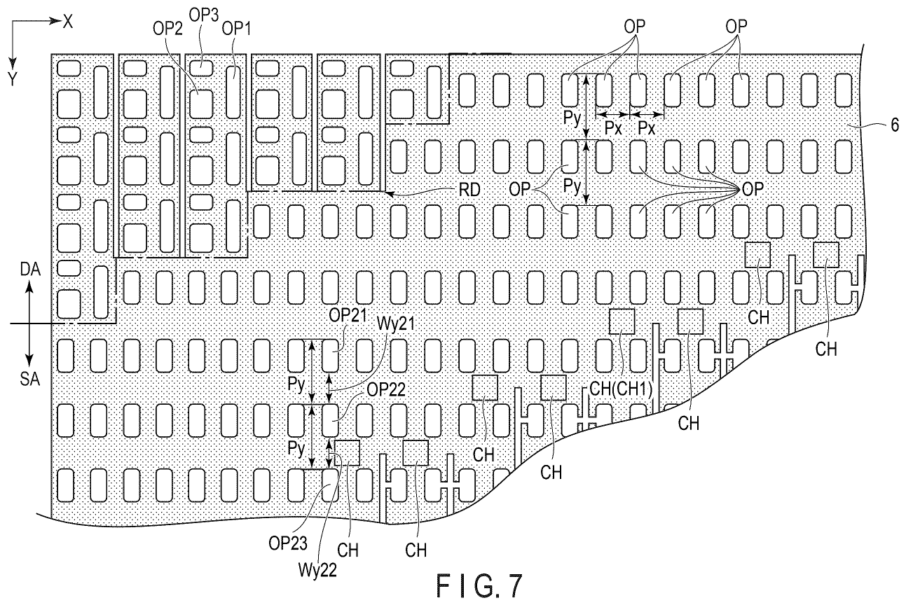

FIG. 7 is a plan view showing an example of the shape of the partition 6 in the vicinity of the round portion RD.

As described above, in the display area DA, the partition 6 is formed in a grating shape having the apertures OP1, OP2, and OP3. In the surrounding area SA, the partition 6 is formed in a grating shape different from that in the display area DA.

That is, in the surrounding area SA, the partition 6 has a plurality of apertures OP arranged in a matrix in the first direction X and the second direction Y. The apertures OP have the same shape and, in the illustrated example, are formed in an elliptical shape or a rectangular shape that extend in the second direction Y. The shape of these apertures OP is different from the shape of any of the apertures OP1, OP2, and OP3 in the display area DA.

The plurality of apertures OP are arranged at a regular pitch Px in the first direction. The plurality of apertures OP are arranged at a regular pitch Py in the second direction Y. The pitch Py is different from the pitch Px. In the illustrated example, the pitch Py is greater than the pitch Px (Py>Px).

In the surrounding area SA, the partition 6 is electrically connected to the power supply line PW shown in FIG. 4 via the plurality of contact holes CH. The plurality of contact holes CH are arranged in a stair step layout along the round portion RD. Each of the contact holes CH is located between two apertures OP adjacent to each other in the second direction Y.

The following focuses a first aperture OP21, a second aperture OP22, and a third aperture OP23 arranged at the regular pitch Py in the second direction Y. Of the plurality of contact holes CH, one contact hole CH is located between the second aperture OP22 and the third aperture OP23. In contrast, no contact hole is located between the first aperture OP21 and the second aperture OP22. In the partition 6, a width Wy21 along the second direction Y between the first aperture OP21 and the second aperture OP22 is equivalent to a width Wy22 along the second direction Y between the second aperture OP22 and the third aperture OP23.

In plan view, the contact hole CH does not overlap any of the second aperture OP22 and the third aperture OP23.

The first aperture OP21, the second aperture OP22, and the third aperture OP23 have the same shape in plan view.

The following focuses on one contact hole CH1 of the plurality of contact holes CH and describes it in detail.

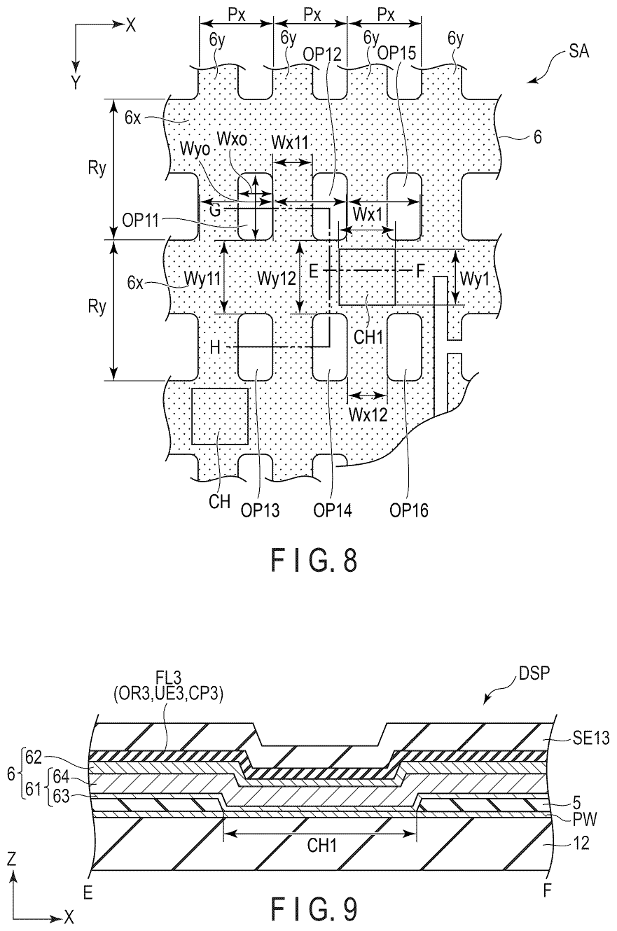

FIG. 8 is a plan view showing an example of the shape of the partition 6 in the vicinity of a contact hole CH1 shown in FIG. 7.

In the surrounding area SA, the partition 6 is formed in a grating shape and has apertures OP11, OP12, OP13, OP14, OP15, and OP16 as a plurality of apertures OP.

The apertures OP11 and OP12 are adjacent to each other in the first direction X.

The apertures OP12 and OP15 are adjacent to each other in the first direction X.

The apertures OP13 and OP14 are adjacent to each other in the first direction X.

The apertures OP14 and OP16 are adjacent to each other in the first direction X.

The apertures OP11 and OP13 are adjacent to each other in the second direction Y.

The apertures OP12 and OP14 are adjacent to each other in the second direction Y.

The apertures OP15 and OP16 are adjacent to each other in the second direction Y.

These apertures OP11, OP12, OP13, OP14, OP15, and OP16 have the same shape. In each of the apertures OP11, OP12, OP13, OP14, OP15, and OP16, a width Wyo along the second direction Y is greater than a width Wxo along the first direction X (Wyo>Wxo).

In the first direction X, the partition 6 has a width Wx11 between the apertures OP11 and OP12 and has a width Wx12 equivalent to the width Wx11 between the apertures OP14 and OP16. Further, in the second direction Y, the partition 6 has a width Wy11 between the apertures OP11 and OP13 and has a width Wy12 equivalent to the width Wy11 between the apertures OP12 and OP14. Each of the width Wx11 and Wx12 is different from the widths Wy11 and Wy12. In the illustrated example, each of the widths WX11 and Wx12 is smaller than the widths Wy11 and Wy12 (Wx11, Wx12<Wy11, Wy12). All of these widths Wx11, Wx12, Wy11, and Wy12 are 40 μm or less.

The contact hole CH1 has a width Wx1 in the first direction X and has a width Wy1 in the second direction Y. The width Wx1 may be equivalent to or different from the width Wy1. The width Wx1 of the contact hole CH1 is greater than the widths Wx11 and Wx12 of the partition 6 (Wx1>Wx11, Wx12). The width Wy1 of the contact hole CHI is smaller than the widths Wy11 and Wy12 of the partition 6 (Wy1<Wy11, Wy12).

The contact hole CH1 is surrounded by four apertures OP12, OP14, OP15, and OP16. The contact hole CH1 is located between the apertures OP12 and OP14 adjacent to each other in the second direction Y and between the apertures OP15 and OP16.

In contrast, no contact hole is provided between the apertures OP11 and OP13.

From another view point, the partition 6 is formed in a grating shape having a plurality of extending portions 6X and a plurality of extending portions 6Y in the surrounding area SA. The plurality of extending portions 6X each extend in the first direction X and are arranged at the regular pitch Py in the second direction Y. The plurality of extending portions 6Y each extend in the second direction Y and are arranged at the regular pitch Px in the first direction X. The contact hole CHI is located at the intersection of one extending portion 6X and one extending portion 6Y.

The pitch Py is different from the pitch Px. In the illustrated example, the pitch Py is greater than the pitch Px (Py>Px).

The width along the second direction Y of the extending portion 6X corresponds to the width Wy11 or the width Wy12 and is greater than the width Wy1 along the second direction Y of the contact hole CH1 (Wy1<Wy11, Wy12).

The width along the first direction X of the extending portion 6Y corresponds to the width Wx11 or the width Wy12 and is smaller than the width Wx1 along the first direction X of the contact hole CH1 (Wx1>Wx11, Wx12).

The width Wy11 along the second direction Y of the extending portion 6X is different from the width Wx11 along the first direction X of the extending portion 6Y. In the illustrated example, the width Wy11 is greater than the width Wx11 (Wy11>Wx11).

FIG. 9 is a schematic cross-sectional view of the display device DSP along the E-F line of FIG. 8. FIG. 9 omits the illustration of the elements located under the insulating layer 12 and the elements located above the sealing layer SE13.

The power supply line PW is provided on the insulating layer 12 and is covered with the inorganic insulating layer 5. The power supply line PW can be formed by the same material and process as those of the lower electrode LE1 and the like.

The contact hole CH1 penetrates the inorganic insulating layer 5.

Of the partition 6, the bottom layer 63 is provided on the inorganic insulating layer 5 and contacts the power supply line PW in the contact hole CH1. The stem layer 64 is provided on the bottom layer 63. The upper portion 62 is provided on the stem layer 64.

In the surrounding area SA, any of the stacked films FL1, FL2, and FL3 provided in the display area DA is provided on the partition 6. In the illustrated example, the stacked film FL3 including the organic layer OR3, the upper electrode UE3, and the cap layer CP3 is provided on the partition 6. The stacked film FL3 is covered with the sealing layer SE13.

The above describes the cross-sectional shape of one contact hole CH1 of the plurality of contact holes CH. The other contact holes CH in the surrounding area SA have the same cross-sectional shape as that of the contact hole CH1. In these contact holes CH, the power supply line PW is electrically connected to the partition 6.

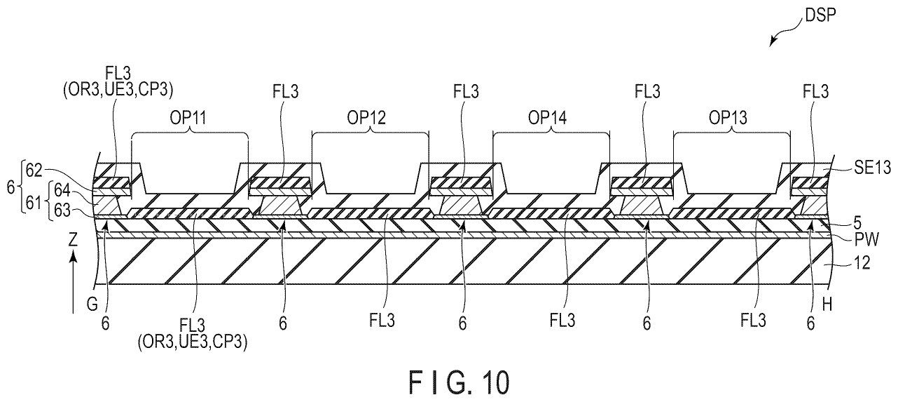

FIG. 10 is a schematic cross-sectional view of the display device DSP along the G-H line of FIG. 8. FIG. 10 omits the illustration of the elements located under the insulating layer 12 and the elements located above the sealing layer SE13.

The inorganic insulating layer 5 has a through hole overlapping the apertures OP11, OP12, OP13, and OP14. Thus, in the areas except the contact hole CH, the power supply line PW is covered with the inorganic insulating layer 5.

The partition 6 has the same cross-sectional shape as that of the display area DA in the surrounding area SA as well. That is, the lower portion 61 of the partition 6 has the bottom layer 63 and the stem layer 64 located on the inorganic insulating layer 5, the upper portion 62 is located on the lower portion 61, and both end portions of the upper portion 62 protrude relative to the side surfaces of the lower portion 61 or the side surfaces of the stem layer 64.

The stacked film FL3 has a first portion located on the upper portion 62 of the partition 6 and a second portion located on the inorganic insulating layer 5 in the apertures OP11, OP12, OP13, and OP14. The first portion and the second portion are spaced apart from each other. As described above, this stacked film FL3 has the organic layer OR3, the upper electrode UE3, and the cap layer CP3.

The sealing layer SE13 continuously covers the first portion and the second portion of the stacked film FL3 and further covers the partition 6 exposed from the stacked film FL3.

The stacked film and the sealing layer that overlap the partition 6 of the surrounding area SA are not limited to the illustrated example and may be the stacked film FL1 and the sealing layer SE11 or the stacked film FL2 and the sealing layer SE12.

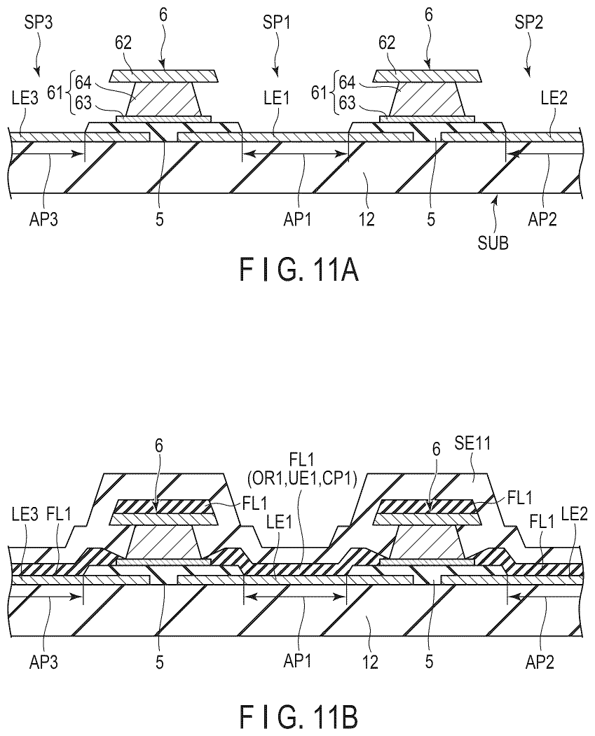

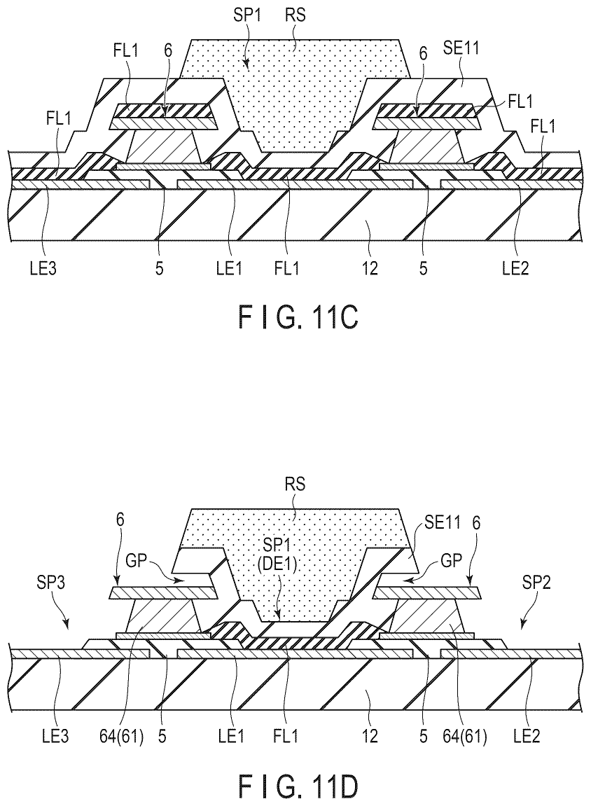

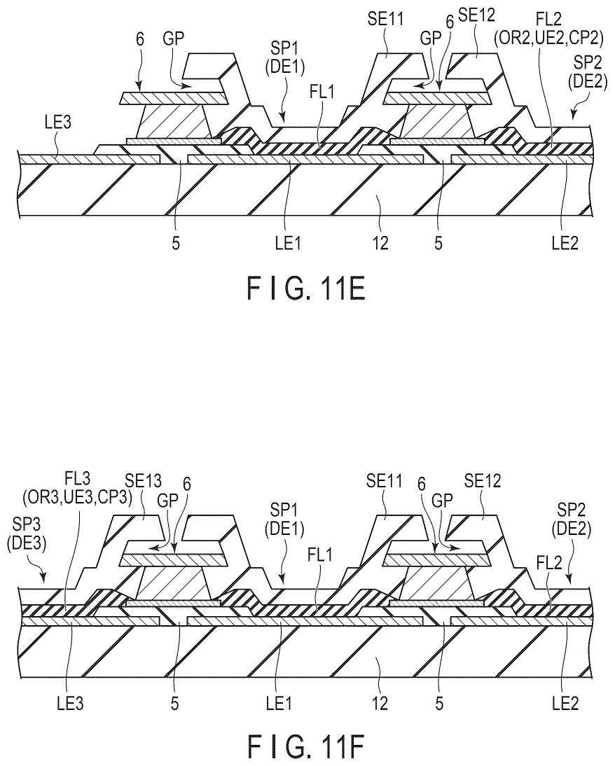

Next, a manufacturing method of the display device DSP will be described. FIG. 11A to FIG. 11F omit the elements below the insulating layer 12.

First, as shown in FIG. 11A, a processing substrate SUB is prepared. The process of preparing the processing substrate SUB includes the process of forming the lower electrode LE1 of the subpixel SP1, the lower electrode LE2 of the subpixel SP2, and the lower electrode LE3 of the subpixel SP3 on the insulating layer 12, the process of forming the inorganic insulating layer 5 having the apertures AP1, AP2, and AP3 overlapping the lower electrodes LE1, LE2, and LE3, respectively, and the process of forming the partition 6 having the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed on the inorganic insulating layer 5 after the formation of the partition 6.

Subsequently, the display element DE1 is formed.

First, as shown in FIG. 11B, the stacked film FL1 is formed on the processing substrate SUB by performing vapor deposition using the partition 6 as a mask. The organic layer OR1, the upper electrode UE1, and the cap layer CP1 included in the stacked film FL1 are successively formed by an evaporation device in a vacuum state. The stacked film FL1 is divided by the partition 6 having an overhang shape.

Subsequently, the sealing layer SE11 continuously covering the stacked film FL1 and the partition 6 is formed. The sealing layer SE11 is formed by depositing inorganic insulating material (for example, a silicon nitride) on the processing substrate SUB in a Chemical Vapor Deposition (CVD) device.

The stacked film FL1 and the sealing layer SE11 are substantially formed in the entire processing substrate SUB and are provided in the subpixels SP2 and SP3 as well as the subpixel SP1 in the display area DA.

Subsequently, as shown in FIG. 11C, a resist RS patterned into a predetermined shape is formed on the sealing layer SE11. The resist RS overlaps the subpixel SP1 and part of the partition 6 around the subpixel SP1.

Next, as shown in FIG. 11D, patterning is performed on the sealing layer SE11 and the stacked film FL1 using the resist RS as a mask. After removing the sealing layer SE11 exposed from the resist RS by performing various etching using the resist RS as a mask, the cap layer CP1, the upper electrode UE1, and the organic layer OR1 included in the stacked film FL1 are removed in series by performing various types of etching using the resist RS as a mask.

These patterning processes make the lower electrode LE2 of the subpixel SP2 and the lower electrode LE3 of the subpixel SP3 exposed.

Subsequently, the resist RS is removed. This process forms the display element DE1 in the subpixel SP1. Further, in the illustrated example, the stacked film FL1 stacked on the partition 6 is removed in the processes before the patterning of the stacked film FL1 and the removal of the resist RS. Thus, the gap GP is formed between the sealing layer SE11 and the partition 6.

Subsequently, as shown in FIG. 11E, the display element DE2 is formed. The procedure of forming the display element DE2 is the same as that of forming the display element DE1. That is, the stacked film FL2 is formed on the lower electrode LE2. The stacked film FL2 includes the organic layer OR2 having the light emitting layer EM2, the upper electrode UE2, and the cap layer CP2. Subsequently, the sealing layer SE12 is formed on the stacked film FL2. Subsequently, a resist is formed on the sealing layer SE12. Then, patterning using this resist as a mask is performed. This sequentially removes the sealing layer SE12 and the stacked film FL2 exposed from the resist. Subsequently, the resist is removed.

This process forms the display element DE2 in the subpixel SP2 and makes the lower electrode LE3 of the subpixel SP3 exposed. In the illustrated example, the stacked film FL2 on the partition 6 is removed at the time of patterning. This forms the gap GP between the sealing layer SE12 and the partition 6.

Next, the display element DE3 is formed as shown in FIG. 11F. The procedure of forming the display element DE3 is the same as that of forming the display element DE1. That is, the stacked film FL3 is formed on the lower electrode LE3. The stacked film FL3 includes the organic layer OR3 having the light emitting layer EM3, the upper electrode UE3, and the cap layer CP3. Subsequently, the sealing layer SE13 is formed on the stacked film FL3. Subsequently, a resist is formed on the sealing layer SE13. Then, patterning using this resist as a mask is performed. This sequentially removes the sealing layer SE13 and the stacked film FL3 exposed from the resist. Subsequently, the resist is removed.

This forms the display element DE3 in the subpixel SP3. In the illustrated example, the stacked film FL3 on the partition 6 is removed at the time of patterning. This forms the gap GP between the sealing layer SE13 and the partition 6.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Then, the resin layer RS1 is formed by applying a resin material. Then, the sealing layer SE2 is formed by stacking an inorganic insulating material. Then, the resin layer RS2 is formed by applying a resin material.

The display device DSP is completed through these processes.

In the above manufacturing process, the stacked film FL1, the sealing layer SE11, the stacked film FL2, the sealing layer SE12, the stacked film FL3, and the sealing layer SE13 are formed in the surrounding area SA as well. For example, if the stacked film FL1 and the sealing layer SE11 are stripped from the processing substrate SUB before the patterning process described with reference to FIG. 11D, these detached films and layers could be a contaminant source in the manufacturing facility. Of the processing substrate SUB, the area from which the stacked film FL1 and the sealing layer SE11 are stripped could be damaged at the time of patterning. Thus, it is important to suppress undesirable stripping of the stacked film FL1 and the sealing layer SE11 in the surrounding area SA. Similarly, it is required to suppress undesirable stripping of the stacked film FL2 and the sealing layer SE12 and the stacked film FL3 and the sealing layer SE13.

According to the present embodiment, the partition 6 is formed in a grating shape having a plurality of apertures OP in the surrounding area SA. Further, the area overlapping the contact hole CH of the partition 6 is formed to have the same planer size as that of the area not overlapping the contact hole CH. That is, locally, in the area overlapping the contact hole CH in particular, the partition 6 does not have the large-area portion.

Thus, for example, in the formation of the stacked film FL1 in the surrounding area SA, the stacked film FL1 is divided by the partition 6. These divided portions of the stacked film FL1 are covered with the sealing layer SE11 and the partition 6. This suppresses undesirable stripping of the stacked film FL1 and the sealing layer SE11.

Similarly, in the formation of the stacked film FL2 in the surrounding area SA, the stacked film FL2 is divided. These divided portions of the stacked film FL2 are covered with the sealing layer SE12. Similarly, in the formation of the stacked film FL3 in the surrounding area SA, the stacked film FL3 is divided. These divided portions of the stacked film FL3 are covered with the sealing layer SE13. This suppresses undesired stripping of the stacked film FL2 and the sealing layer SE12 and the stacked film FL3 and the sealing layer SE13.

This configuration can improve the yield in the manufacturing of the display device DSP.

As a result of various studies conducted by the inventor, it has been confirmed that the stacked films are not stripped when both of the width Wx11 along the first direction X of the partition 6 and the width Wx12 along the second direction Y are 40 μm or less. The partition 6 of the surrounding area SA functions to supply the partition 6 of the display area DA with common voltage supplied from the power supply line PW. Thus, the width of the partition 6 of the surrounding area SA should not be excessively small. The width is desirably 10 μm or more.

Next, several other configuration examples are described.

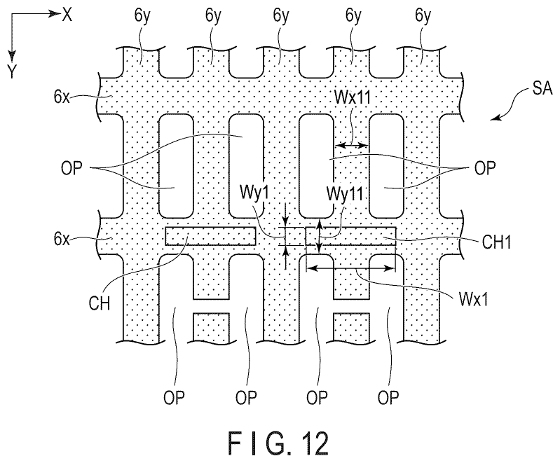

FIG. 12 is a plan view showing another example of the shape of the partition 6 in the vicinity of the contact hole CH1.

The example shown in FIG. 12 differs from the example shown in FIG. 8 in that the width Wy11 along the second direction Y of the extending portion 6X extending in the first direction X is equivalent to the width Wx11 along the first direction X of the extending portion 6Y extending in the second direction Y in the partition 6 (Wy11=Wx11).

Further, the example shown in FIG. 12 differs from the example shown in FIG. 8 in that the shape of each of the plurality of contact holes CH, including the contact hole CH1, is extended in the first direction X.

The contact hole CH1 is located at the intersection of one extending portion 6X and one extending portion 6Y. The width Wx1 along the first direction X of the contact hole CHI is greater than the width Wy1 along the second direction Y of the contact hole CH1 (Wy1<Wx1). Further, the width Wy11 of the extending portion 6X is greater than the width Wy1 of the contact hole CH1 (Wy1<Wy11). The width Wx11 of the extending portion 6Y is smaller than the width Wx1 of the contact hole CH1 (Wx1>Wx11).

In this configuration as well, the advantages described above can be achieved. In addition, the extending portion 6X of the partition 6 has the same width as the extending portion 6Y in the surrounding area SA. Thus, at the time of forming the stacked film on the extending portion 6X and the extending portion 6Y, the stress acting on the stacked film on the extending portion 6X and the stress acting on the stacked film on the extending portion 6Y are equalized. Thus, local stripping of the stacked film is suppressed.

Further, the contact hole CH is extended in the first direction X in the area overlapping the partition 6. This suppresses an increase in connection resistance accompanying a reduction in the planer size of the contact hole CH.

In the example shown in FIG. 12, the contact hole CH is extended in the first direction X, but may be extended in the second direction Y.

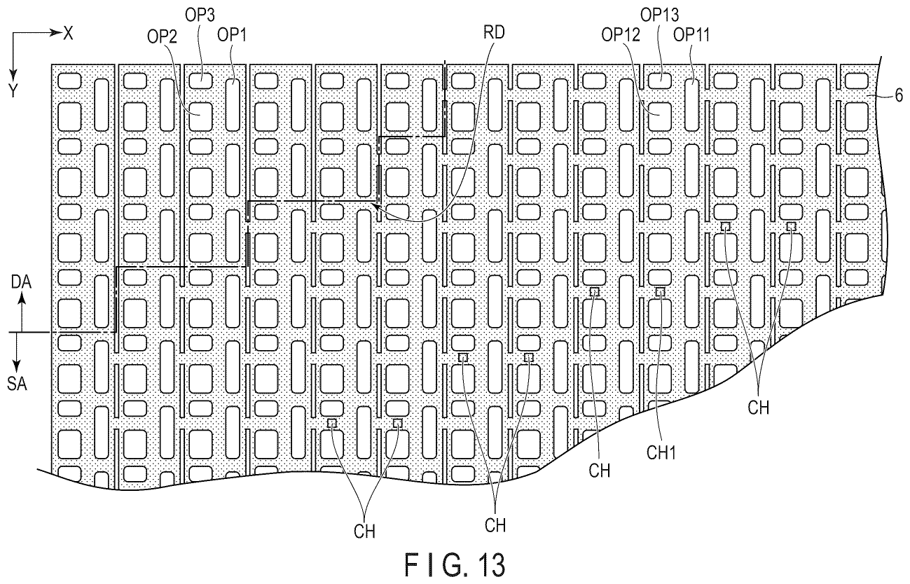

FIG. 13 is a plan view showing an example of the shape of the partition 6 in the vicinity of the round portion RD.

The example shown in FIG. 13 differs from the example shown in FIG. 7 in that the partition 6 is formed in the same grating shape as the display area DA in the surrounding area SA.

As described above, in the display area DA, the partition 6 is formed in a grating shape having the apertures OP1, OP2, and OP3. In the surrounding area SA, the partition 6 is formed in a grating shape having the apertures OP11, OP12, and OP13. The aperture OP11 has the same shape as the aperture OP1. The aperture OP12 has the same shape as the aperture OP2. The aperture OP13 has the same shape as the aperture OP3.

In the surrounding area SA, the partition 6 is electrically connected to the power supply line PW shown in FIG. 4 via the plurality of contact holes CH. The plurality of contact holes CH are arranged in a stair step layout along the round portion RD. Each of the contact holes CH is located between two apertures OP adjacent to each other in the second direction Y. The following focuses on one contact hole CHI of the plurality of contact holes CH and describes it in detail.

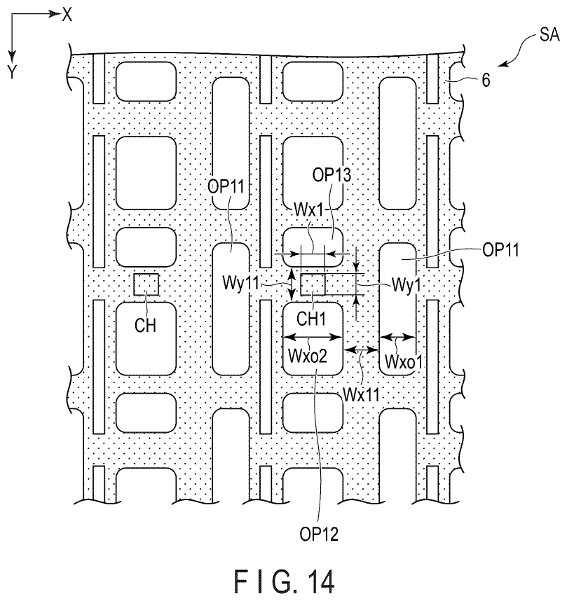

FIG. 14 is a plan view showing an example of the shape of the partition 6 in the vicinity of the contact hole CH1 shown in FIG. 13.

The partition 6 is formed in a grating shape in the surrounding area SA and has the apertures OP11, OP12, OP13 as a plurality of apertures OP.

The apertures OP11 and OP12 are adjacent to each other in the first direction X.

The apertures OP11 and OP13 are adjacent to each other in the first direction X.

The apertures OP12 and OP13 are adjacent to each other in the second direction Y.

These apertures OP11, OP12, and OP13 have different shapes. For example, the aperture OP11 extends in the second direction Y. The aperture OP13 extends in the first direction X. The aperture OP12 extends in the second direction Y, but is shorter than the aperture OP11. With respect to the width along the first direction X, a width Wxo1 of the aperture OP11 is smaller than a width Wxo2 of the aperture OP12 (Wxo1<Wxo2). The width along the first direction X of the aperture OP13 is equivalent to the width Wxo2.

The partition 6 has the width Wx11 between the apertures OP11 and OP12 in the first direction X. The partition 6 also has the width Wy11 between the apertures OP12 and OP13 in the second direction Y. Both of the widths Wx11 and Wy11 are 40 μm or less.

The contact hole CH1 is located between the apertures OP12 and OP13 in the second direction Y. The contact hole CH1 has the width Wx1 in the first direction X and has the width Wy1 in the second direction Y. In the illustrated example, the width Wx1 is equivalent to the width Wy1 (Wx1=Wy1).

The width Wx1 of the contact hole CH1 is smaller than the width Wxo2 of the aperture OP12 (Wx1<Wxo2). The width Wy1 of the contact hole CH1 is smaller than the width Wy11 of the partition 6 (Wy1<Wy11).

The cross-sectional structure including the contact hole CH1 is the same as the one shown in

FIG. 9. Furthermore, the cross-sectional structure of the apertures OP11, OP12, and OP13 is the same as the structure shown in FIG. 10. That is, the inorganic insulating layer 5 does not have any through holes overlapping the apertures OP11, OP12, and OP13.

In this configuration as well, the advantages described above can be achieved.

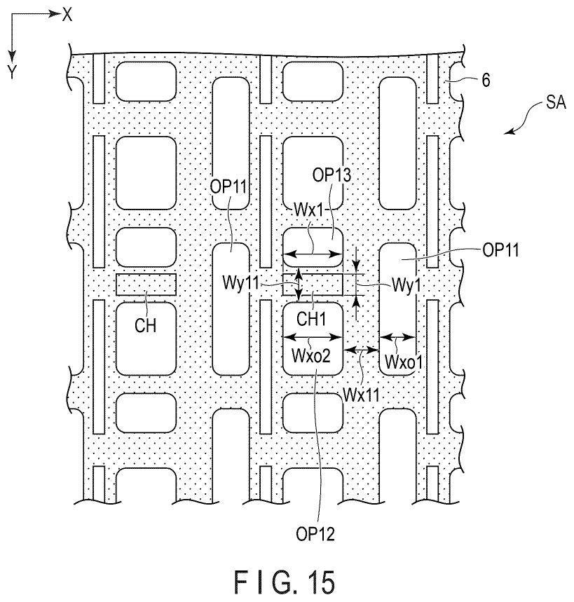

FIG. 15 is a plan view showing another example of the shape of the partition 6 in the vicinity of the contact hole CH1 shown in FIG. 13.

The example shown in FIG. 15 differs from the example shown in FIG. 14 in that the width Wx1 along the first direction X of the contact hole CHI differs from the width Wy1 along the second direction Y. In the illustrated example, the width Wx1 is greater than the width Wy1 (Wx1>Wy1).

In this configuration as well, the advantages described above can be achieved.

Further, the contact hole CH is extended in the first direction X in the area overlapping the partition 6. This suppresses an increase in connection resistance accompanying a reduction in the planer size of the contact hole CH.

In the example shown in FIG. 15, the contact hole CH is extended in the first direction X, but may be extended in the second direction Y.

In the above embodiment, for example, the contact hole CH1 corresponds to the first contact hole. The aperture OP11 corresponds to the first aperture. The aperture OP12 corresponds to the second aperture. The aperture OP13 corresponds to the third aperture. The aperture OP14 corresponds to the fourth aperture.

In the partition 6, the width Wy11 corresponds to the first width. The width Wy12 corresponds to the second width. The extending portion 6X corresponds to the first extending portion. The extending portion 6Y corresponds to the second extending portion. The pitch Py corresponds to the first pitch. The pitch Px corresponds to the second pitch.

As described above, the present embodiment can provide the display device capable of improving the yield.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a display element provided in a display area for displaying an image;
an inorganic insulating layer provided across the display area and a surrounding area located outside the display area;
a partition provided on the inorganic insulating layer, having conductivity, and surrounding the display element in the display area; and
a power supply line covered with the inorganic insulating layer, wherein
an outer edge of the display area has a round portion,
the power supply line is provided along the round portion in the surrounding area and is electrically connected to the partition via a plurality of contact holes penetrating the inorganic insulating layer, and
the plurality of contact holes are arranged in a stair step layout along the round portion.

2. The display device of claim 1, wherein
the partition is formed in a grating shape having a first aperture and a second aperture adjacent to each other in a first direction and a third aperture and a fourth aperture adjacent to each other in the first direction in the surrounding area,
the first aperture and the third aperture are adjacent to each other in a second direction intersecting the first direction,
the second aperture and the fourth aperture are adjacent to each other in the second direction,
the partition has a first width between the first aperture and the third aperture in the second direction and a second width between the second aperture and the fourth aperture,
the second width is equivalent to the first width,
the plurality of contact holes include a first contact hole located between the second aperture and the fourth aperture, and
no contact hole is located between the first aperture and the third aperture.

3. The display device of claim 2, wherein
the second width is 40 μm or less.

4. The display device of claim 2, wherein
the first aperture, the second aperture, the third aperture, and the fourth aperture have a same shape.

5. The display device of claim 4, wherein
in each of the first aperture, the second aperture, the third aperture, and the fourth aperture, a width along the second direction is greater than a width along the first direction.

6. The display device of claim 1, wherein
the partition has a first extending portion extending in a first direction and a second extending portion extending in a second direction intersecting the first direction in the surrounding area,
the plurality of contact holes include a first contact hole located at an intersection of the first extending portion and the second extending portion,
a width along the second direction of the first extending portion is greater than a width along the second direction of the first contact hole, and
a width along the first direction of the second extending portion is smaller than a width along the first direction of the first contact hole.

7. The display device of claim 6, wherein
the width along the second direction of the first extending portion differs from the width along the first direction of the second extending portion.

8. The display device of claim 1, wherein
the partition has a first extending portion extending in a first direction and a second extending portion extending in a second direction intersecting the first direction in the surrounding area,
the plurality of contact holes include a first contact hole located at an intersection of the first extending portion and the second extending portion, and
a width along the second direction of the first extending portion is equivalent to a width along the first direction of the second extending portion.

9. The display device of claim 8, wherein
a width along the first direction of the first contact hole is greater than a width along the second direction of the first contact hole.

10. The display device of claim 1, wherein
the partition is formed in a grating shape having a first aperture, a second aperture, and a third aperture in the surrounding area,
the first aperture and the second aperture are adjacent to each other in a first direction,
the first aperture and the third aperture are adjacent to each other in the first direction,
the second aperture and the third aperture are adjacent to each other in a second direction intersecting the first direction, and
the plurality of contact holes include a first contact hole located between the second aperture and the third aperture in the second direction.

11. The display device of claim 10, wherein
the first aperture, the second aperture, and the third aperture have shapes different from one another.

12. The display device of claim 10, wherein
the partition has a width of 40 μm or less in the second direction between the second aperture and the third aperture.

13. The display device of claim 10, wherein
a width along the first direction of the first contact hole is equivalent to a width along the second direction of the first contact hole.

14. The display device of claim 10, wherein
a width along the first direction of the first contact hole is greater than a width along the second direction of the first contact hole.

15. The display device of claim 10, wherein
the partition is formed in a same grating shape in the display area and the surrounding area.

16. A display device, comprising:
a display element provided in a display area for displaying an image;
an inorganic insulating layer provided across the display area and a surrounding area located outside the display area;
a partition provided on the inorganic insulating layer, having conductivity, and surrounding the display element in the display area; and
a power supply line covered with the inorganic insulating layer, wherein
the power supply line is electrically connected to the partition via a contact hole penetrating the inorganic insulating layer in the surrounding area,
the partition is formed in a grating shape having a plurality of first extending portions and a plurality of second extending portions in the surrounding area,
the plurality of first extending portions each extend in a first direction and are arranged at a first pitch in a second direction intersecting the first direction,
the plurality of second extending portions each extend in the second direction and are arranged at a second pitch in the first direction, and
the contact hole is located at an intersection of one of the plurality of first extending portions and one of the plurality of second extending portions.

17. The display device of claim 16, wherein
the first pitch differs from the second pitch.

18. The display device of claim 16, wherein
the first pitch is greater than the second pitch.

19. The display device of claim 16, wherein
a width along the second direction of each of the plurality of first extending portions differs from a width along the first direction of each of the plurality of second extending portions.

20. The display device of claim 16, wherein
a width along the second direction of each of the plurality of first extending portions is greater than a width along the first direction of each of the plurality of second extending portions.

21. The display device of claim 16, wherein
a width along the second direction of each of the plurality of first extending portions is greater than a width along the second direction of the contact hole, and
a width along the first direction of each of the plurality of second extending portions is smaller than a width along the first direction of the contact hole.

22. A display device, comprising:
a display element provided in a display area for displaying an image;
an inorganic insulating layer provided across the display area and a surrounding area located outside the display area;
a partition provided on the inorganic insulating layer, having conductivity, and surrounding the display element in the display area; and
a power supply line covered with the inorganic insulating layer, wherein
the power supply line is electrically connected to the partition via a contact hole penetrating the inorganic insulating layer in the surrounding area,
the partition is formed in a grating shape having a plurality of apertures in the surrounding area,
the plurality of apertures have a first aperture, a second aperture, and a third aperture arranged at a regular pitch in a direction,
the contact hole is located between the second aperture and the third aperture, and
a width between the first aperture and the second aperture is equivalent to a width between the second aperture and the third aperture in the partition.

23. The display device of claim 22, wherein
the contact hole does not overlap any of the second aperture and the third aperture in plan view.

24. The display device of claim 22, wherein
the first aperture, the second aperture, and the third aperture have a same shape.

25. The display device of claim 2, wherein
the inorganic insulating layer does not have a through hole overlapping the first aperture, the second aperture, and the third aperture.

26. The display device of claim 1, wherein
the partition has:
a lower portion located on the inorganic insulating layer in the display area and the surrounding area, contacting the power supply line in the surrounding area, and formed of a conductive material; and
an upper portion located on the lower portion and having an end portion protruding relative to a side surface of the lower portion.

27. The display device of claim 26, wherein
the display element comprises:
a lower electrode having a peripheral portion covered with the inorganic insulating layer;
an organic layer located on the lower electrode and having a light emitting layer; and
an upper electrode located on the organic layer and contacting the lower portion of the partition.

28. The display device of claim 26, further comprising:
a stacked film having a first portion located on the upper portion of the partition and a second portion located on the inorganic insulating layer and spaced apart from the first portion in the surrounding area; and
a sealing layer formed of an inorganic insulating material and continuously covering the first portion and the second portion of the stacked film.

29. The display device of claim 28, wherein
the stacked film includes:
an organic layer located on the inorganic insulating layer and having a light emitting layer;
an upper electrode located on the organic layer and contacting the lower portion of the partition; and
a cap layer located on the upper electrode.
